(19) United States
(12) Patent Application Publication
(10) Pub. No.: US 2025/0170597 A1
(43) Pub. Date: May 29, 2025

(54) ADJUSTABLE NOZZLE DEVICE

(71) Applicant: Taiwan Semiconductor Manufacturing Co., Ltd., Hsinchu (TW)

(72) Inventors: Nathan Ang Wee Kiat, Singapore (SG); Kai-Shiung Hsu, Hsinchu City (TW); Fan Hsuan Chien, Tainan City (TW); Pei Yen Cheng, Tainan City (TW); Jyh-Nan Lin, Hsinchu City (TW); Chang-Feng Tsai, New Taipei City (TW)

(73) Assignee: Taiwan Semiconductor Manufacturing Co., Ltd., Hsinchu (TW)

(21) Appl. No.: 18/521,726

(22) Filed: Nov. 28, 2023

(51) Int. Cl. B05B 1/18; H01L 21/67

(52) U.S. Cl. CPC B05B 1/30; B05B 1/16; B05B 1/3046; H01L 21/67051

(57) ABSTRACT

An apparatus and a method for semiconductor manufacturing processes are disclosed. The apparatus includes a wafer holder configured to hold a wafer, a nozzle disposed above the wafer and configured to provide a material to the wafer, and a nozzle control device configured to adjust a configuration of the nozzle to improve a uniformity of the material disposed onto the wafer. The method include loading the wafer into a chamber, feeding the material into the chamber through the nozzle, measuring a thickness profile of the material disposed onto the wafer, and adjusting a configuration of the nozzle based on the thickness profile.

### BACKGROUND

In semiconductor manufacturing, some fabrication processes, such as a deposition process or a cleaning process, are performed by dispersing materials on semiconductor wafers. During these fabrication processes, the uniformity of the materials dispersed onto semiconductor wafers can vary, thus adversely affecting wafer yield and IC performance.

### BRIEF DESCRIPTION OF THE DRAWINGS

Aspects of this disclosure are best understood from the following detailed description when read with the accompanying figures.

FIG. 1A illustrates a semiconductor manufacturing system, in accordance with some embodiments.

FIG. 1B illustrates a bottom view of a showerhead with nozzles, in accordance with some embodiments.

FIGS. 2A and 2B illustrate cross-sectional views of a nozzle device having an orifice with an adjustable size, in accordance with some embodiments.

FIGS. 2C and 2D illustrate cross-sectional views of a nozzle device, in accordance with some embodiments.

FIGS. 3A and 3B illustrate cross-sectional views of a nozzle device having a nozzle with an adjustable configuration, in accordance with some embodiments.

FIGS. 4A and 4B illustrate cross-sectional views of a nozzle device having a nozzle with an adjustable configuration, in accordance with some embodiments.

FIGS. 5A and 5B illustrate cross-sectional views of a nozzle device having a nozzle with an adjustable configuration, in accordance with some embodiments.

FIGS. 5C and 5D illustrate planar distributions of a material dispersed by nozzle devices, in accordance with some embodiments.

FIGS. 6A and 6B illustrate a cross-sectional side view and a bottom view of a nozzle device having a nozzle with an adjustable configuration, respectively, in accordance with some embodiments.

FIG. 6C illustrates a planar distribution of a material dispersed by a nozzle device, in accordance with some embodiments.

FIG. 6D illustrates a bottom view of a showerhead with nozzles having an adjustable configuration, in accordance with some embodiments.

FIG. 7 illustrates a bottom view of a showerhead with nozzles having an adjustable configuration, in accordance with some embodiments.

FIG. 8 illustrates a bottom view of a nozzle device having a nozzle with an adjustable configuration, in accordance with some embodiments.

FIG. 9 illustrates a bottom view of a nozzle device having a nozzle with an adjustable configuration, in accordance with some embodiments.

FIG. 10 illustrates a flow diagram of a method for performing a semiconductor manufacturing process with a nozzle device, in accordance with some embodiments.

FIG. 11A illustrates a configuration of nozzles on multiple sections of a showerhead, in accordance with some embodiments.

FIG. 11B illustrates a reference profile of a material dispersed onto a wafer, in accordance with some embodiments.

FIG. 11C illustrates a thickness profile of a material dispersed onto a wafer, in accordance with some embodiments.

FIG. 12 illustrates a block diagram of an exemplary computer system, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows can include embodiments in which the first and second features are formed in direct contact, and can also include embodiments in which additional features can be formed between the first and second features, such that the first and second features can not be in direct contact. As used herein, the formation of a first feature on a second feature means the first feature is formed in direct contact with the second feature. In addition, the present disclosure can repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

It is noted that references in the specification to “one embodiment,” “an embodiment,” “an example embodiment,” “exemplary,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

Semiconductor manufacturing processes can include operations to disperse a material (e.g., a precursor material, a chemical solution, and deionized (DI) water) onto a wafer for various purposes, such as forming device layers/structures or cleaning the wafer. The operations can be performed by dispersing the material through nozzles disposed above the wafer. A uniformity of a layer of the material dispersed onto the wafer can affect the quality of semiconductor devices formed on the wafer.

The uniformity of the layer of the material dispersed onto the wafer can be affected by various factors, such as chemical properties (e.g., reactivity, pH value, and stability), physical properties (e.g., temperature, pressure, and being a gas, a liquid, or a plasma form), and mechanical properties (e.g., viscosity, flow velocity, and compressibility) of the material. These factors can vary over the duration of the manufacturing process and can affect the uniformity of the layer of the material dispersed onto the wafer. For example, nozzles used to disperse the material can be susceptible to condensation or accumulation of the material in the nozzles. The resulting partial or total clogs formed in the nozzles can cause abnormal performance of the nozzles and affect the uniformity of the material dispersed onto the wafer. These nozzles are subject to be replaced, which can be time-consuming, labor-consuming, and jeopardize throughput of a semiconductor device manufacturing process.

To address the abovementioned challenges, the present disclosure provides apparatuses and methods for semiconductor manufacturing processes implementing an adjustable nozzle device. The apparatus can include nozzles with adjustable configurations (such as dimensions and direction of the nozzle) that facilitate the control of a flowrate and a direction of material dispersed by the nozzles, such that the uniformity of the material dispersed onto the wafer can be improved. The methods can include collecting data about a thickness profile of the material dispersed onto the wafers, comparing the thickness profile with a reference profile, and adjusting the configurations of the nozzles to optimize the uniformity of the material dispersed onto the wafer.

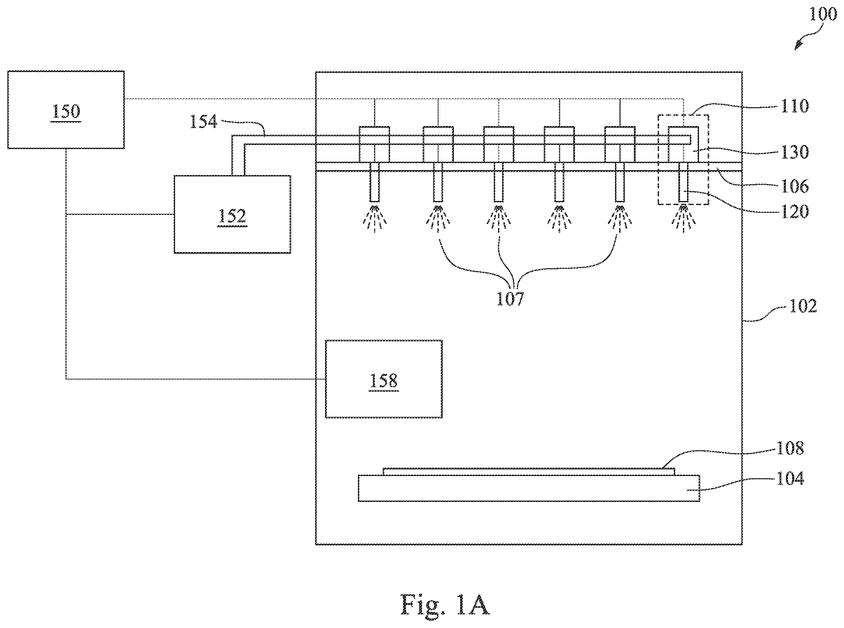

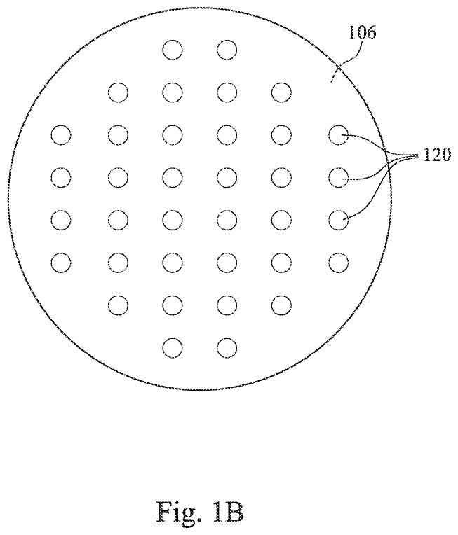

FIG. 1A illustrates a system 100 for semiconductor manufacturing, in accordance with some embodiments. System 100 can include a chamber 102, a wafer holder 104 in chamber 102, and a showerhead 106 in chamber 102 and disposed above wafer holder 104. Wafer holder 104 is configured to hold a wafer 108. System 100 can further include one or more nozzle devices 110. Each nozzle device 110 can include a nozzle 120 mounted on showerhead 106 and configured to deliver a material 107 into chamber 102. Nozzles 120 can be coupled to a material supply device 152 outside chamber 102 via a material supply channel 154. Each nozzle device 110 can further include one or more nozzle control devices 130 coupled to nozzle 120 and configured to control one or more configurations of nozzle 120. System 100 can further include an analyzer device 158 configured to measure a uniformity of material 107 dispersed onto wafer 108. System 100 can further include a control device 150 coupled to nozzle control devices 130, material supply device 152, and analyzer device 158.

System 100 can include additional components required for operation. By way of example and not limitation, such components can include transfer devices, robotic arms, view ports, pumps, valves, exhaust lines, heating elements, gas and chemical supply lines, controllers, valves, and external and internal electrical connections to other components of the cluster tool (e.g., temperature sensors, pressure sensors, chemical analyzers, temperature controllers, and pressure controllers). These additional components may not be depicted in FIG. 1A but are within the spirit and scope of this disclosure.

Chamber 102 can be a processing chamber to provide a vacuum environment to conduct semiconductor device manufacturing processes on wafer 108 that requires a vacuum environment (e.g., a vacuum pressure below 10⁻⁴ torr) to preserve, for example, a desired mean-free-path of reacting gases, plasma, and/or electrons in chamber 102 during semiconductor device manufacturing processes. In some embodiments, chamber 102 can be a deposition chamber to perform thin-film deposition on wafer 108 by depositing material 107 on wafer 108. In some embodiments, chamber 102 can be a cleaning chamber to perform a cleaning operation on wafer 108 by dispersing material 107 in a liquid or a gas form onto wafer 108 to remove contaminations on wafer 108.

Wafer holder 104 can be configured to hold wafer 108 during the semiconductor manufacturing processes. In some embodiments, wafer holder 104 can include a vacuum suck to secure wafer 108. In some embodiments, wafer holder 104 can include screws and pins to fix a position of wafer 108 on wafer holder 104. In some embodiments, wafer holder 104 can provide a controllable temperature condition for wafer 108. For example, wafer holder 104 can include a heater and/or a cooling channel through which coolant can flow. In some embodiments, wafer holder 104 can be driven by a motor and can rotate during the manufacturing processes. In some embodiments, wafer holder 104 can be configured to hold multiple wafers, similar to wafer 108, to be processed. In some embodiments, system 100 can include multiple wafer holders, similar to wafer holder 104, disposed in chamber 102.

Showerhead 106 can be a platform on which nozzle devices 110 is disposed. Referring to FIG. 1B, which illustrates a bottom view of showerhead 106, showerhead 106 can have a round shape, with nozzles 120 evenly disposed on a bottom surface of showerhead 106. In some embodiments, showerhead 106 can have a different shape, such as a square shape, a polygon shape, an oval shape, or an irregular shape. In some embodiments, nozzles 120 can be disposed on the bottom surface of showerhead 106 in an uneven manner. Referring back to FIG. 1A, in some embodiments, showerhead 106 can include mounting holes with screw threads for nozzles 120 to be mounted on the bottom surface of showerhead 106. In some embodiments, nozzle control devices 130 can be disposed on a top surface of showerhead 106 and coupled with nozzles 120 through showerhead 106. In some embodiments, material supply channel 154 can be disposed on the top surface of showerhead 106 and connect with nozzles 120 through showerhead 106 to supply material 107 through nozzles 120 into chamber 102.

Each nozzle 120 can include a passage (not shown in FIG. 1A) in which material 107 can flow through and be supplied into chamber 102. In some embodiments, nozzles 120 can be the same type of nozzle supplying the same material. In some embodiments, nozzles 120 can include different types of nozzles supplying different materials for different processing purposes. For example, nozzles 120 can include a first type of nozzles specialized to provide a first material (e.g., a precursor gas for forming thin films on wafer 108) and a second type of nozzles specialized to provide a second material (e.g., a cleaning solution for cleaning wafer 108).

In some embodiments, for each nozzle device 110, nozzle 120 can have configurations controlled by nozzle control device 130. In some embodiments, nozzle 120 can be controlled such that a size of the passage of nozzle 120 can be adjusted, hence a flowrate of material 107 flowing through nozzle 120 can be adjusted. In some embodiments, nozzle 120 can include a valve in the passage and controlled by nozzle control device 130 to adjust the flowrate of material 107 flowing through nozzle 120. In some embodiments, a direction of nozzle 120 can be controlled by nozzle control device 130, such that a dispersion direction of material 107 supplied into chamber 102 can be adjusted. For example, nozzle 120 can include a ball-joint facilitating a rotation along certain rotation axes to adjust the direction of nozzle 120.

In some embodiments, all nozzles 120 can have one or more of the same types of adjustable configuration (e.g., the size of the passage and/or the direction). In some embodiments, different types of nozzles 120 having different adjustable configurations can be mounted on showerhead 106. For example, some nozzles of nozzles 120 can have their sizes of the passages adjustable while some other nozzles of nozzles 120 can have their directions adjustable.

Nozzle control device 130 can be coupled to nozzle 120 and configured to control the configurations of nozzle 120. Nozzle control device 130 can include one or more actuators (not shown in FIG. 1A) providing linear or circular motions to adjust the configurations of nozzle 120. For example, nozzle control device 130 can include an electrical motor, a hydraulic actuator, a pneumatic actuator, a magnetic actuator, a piezoelectric actuator, a shape-memory allay (SMA) actuator, a thermal actuator, and/or a combination thereof. In some embodiments, nozzle control device 130 can include a manual actuator (e.g., a manual knob or a press button) such that the configurations of nozzle 120 can be tuned manually by a user. In some embodiments, the manual actuator can include increment markings quantitatively indicating the configurations of nozzle 120 (e.g., an angle of the direction of nozzle 120 or the size of the passage of nozzle 120).

In some embodiments, nozzles 120 can be labelled for the user to identify efficiently. In some embodiments, nozzle control device 130 can further include motion transmission mechanics (not shown in FIG. 1A) to couple the actuator with nozzle 120. The motion transmission mechanics can be configured to deliver and/or transform the linear or circular motions generated by the actuator to nozzle 120, so that the configurations of nozzle 120 can be adjusted and/or fine-tuned. The motion transmission mechanics can include mechanical components, such as shafts, hinges, sleeves, gears, worm gears, gear racks, springs, stoppers, and/or a combination thereof, to facilitate the delivery and/or transformation of the linear or circular motions generated by the actuator.

Material supply device 152 can include one or more containers storing one or more materials in solid, liquid, and/or gas forms, and supply the materials, such as material 107, to nozzles 120 through material supply channel 154. In some embodiments, material supply device 152 can include containers storing materials for forming structures in wafer 108. For example, material supply device 152 can include containers storing precursor gases for a chemical vapor deposition (CVD) process, a physical vapor deposition (PVD), an atomic layer deposition (ALD) process, and a molecular beam epitaxy (MBE) process. In some embodiments, material supply device 152 can include containers storing materials for performing a cleaning operation on wafer 108. For example, material supply device 152 can include containers storing DI water, cleaning solutions, nitrogen gas, and inert gas.

Analyzer device 158 can be disposed above a surface of wafer 108 and configured to measure a uniformity of material 107 dispersed onto wafer 108. In some embodiments, analyzer device 158 can implement an optical method to measure a thickness of material 105 on wafer 108. For example, analyzer device 158 can include an ellipsometer to measure a thickness profile of material 105 dispersed onto wafer 108, by scanning the top surface of wafer 108 or sampling different locations on the top surface of wafer 108. In some embodiments, analyzer device 158 can implement other methods, such as acoustic or mechanical methods, to measure the uniformity of material 105 dispersed onto wafer 108. In some embodiments, analyzer device 158 can be mounted on a robotic arm (not shown in FIG. 1A) configured to drive analyzer device 158 across the top surface of wafer 108 to measure the uniformity of material 107 dispersed onto wafer 108. In some embodiments, analyzer device 158 can generate control wafer data based on the thickness profile of material 107 dispersed onto wafer 108.

Control device 150 can be configured to control semiconductor manufacturing processes. In some embodiments, control device 150 can include a computer system. As shown in FIG. 1A, control device 150 can be configured to communicate with nozzle control devices 130, material supply device 152, and analyzer device 158. In some embodiments, the communication between control device 150 and the above elements can be via electrical cables and/or wireless means. In some embodiments, during a measurement operation, control device 150 can be configured to send commands to analyzer device 158 and control analyzer device 158 to measure the thickness profile of material 107 dispersed onto wafer 108 and to receive the data about the thickness profile sent by analyzer device 158. In some embodiments, control device 150 can be configured to compare the thickness profile to a predetermined reference profile and to calculate a scheme to adjust the configurations of nozzles 120 according to a difference between the thickness profile and the reference profile, so as to improve the uniformity of the thickness of material 107 dispersed onto wafer 108. In some embodiments, during a calibration operation, according to the calculated scheme, control device 150 can be configured to send calibration commands to nozzle control devices 130 to adjust the configurations of nozzles 120. In some embodiments, control device 150 can be configured to repeat the measurement process and the calibration process to adjust the configurations of nozzles 120 until the difference between the thickness profile and the reference profile can be reduced to be below a predetermined threshold value. In some embodiments, once the difference between the thickness profile and the reference profile is below the threshold value, control device 150 can be configured to perform a manufacturing operation (e.g., a deposition operation or a cleaning operation), by controlling material supply device 152 to provide material 107 to nozzles 120 via material supply channel 154. In some embodiments, during the manufacturing operation, control device 150 can be configured to control analyzer device 158 to perform a real time measurement about the thickness profile of material 107 dispersed onto wafer 108, determine if the configurations of one or more of nozzles 120 need to be adjusted, and if necessary, control nozzle control devices 130 to perform a real time adjustment of the configurations of nozzles 120.

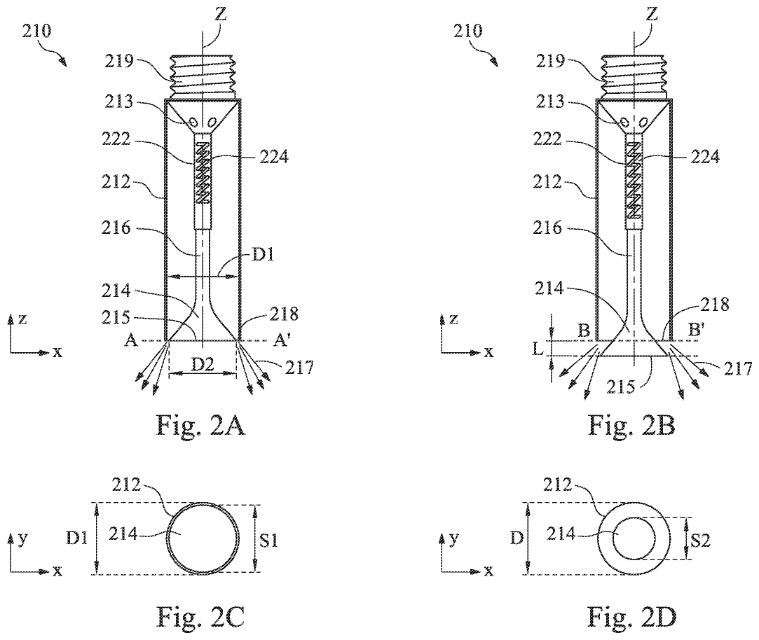

The present disclosure provides different embodiments of nozzle devices 110, as described in the following with reference to FIGS. 2A-11.

FIGS. 2A and 2B illustrate cross-sectional views of a nozzle device 210 having an orifice 218 with an adjustable size, in accordance with some embodiments. FIGS. 2C and 2D illustrate cross sections views of nozzle device 210 along the A-A′ line in FIG. 1A and the B-B′ line in FIG. 1B, respectively. Nozzle device 210 can be one of the nozzle devices 110 in FIG. 1A. Nozzle device 210 can include a tube 212 forming a passage through which a material 217 can be supplied into a chamber (e.g., chamber 102 in FIG. 1A). In some embodiments, tube 212 can have a cylindrical cross sectional shape. In some embodiments, the cross section of tube 212 can have other shapes, such as a rectangular shape, a polygon shape, an oval shape, and an irregular shape. Nozzle device 210 can further include an actuator 222 disposed in tube 212, a blocking device 214 disposed close to an end of tube 212, and a rod 232 connecting actuator 222 and blocking device 214. In some embodiments, blocking device 214 can have a cone shape and can be coaxially disposed within tube 212 along a Z axis of tube 212. In some embodiments, nozzle device 210 can further include a screw 219 disposed on another end of tube 212. Screw 219 is configured to mount nozzle device 210 onto a bottom surface of a showerhead (e.g., showerhead 106 in FIG. 1A). Nozzle device 210 can further include channels 213 disposed through screw 219. Channels 213 can be coupled to a material supply channel (e.g., material supply channel 154 in FIG. 1A) and configured to provide material 217 into tube 212.

In some embodiments, a configuration of a position of blocking device 214 along the Z axis can be controlled by actuator 222, such that the end of tube 212 is partially or fully blocked by blocking device 214. In some embodiments, tube 212 can have a diameter D1, and a bottom periphery 215 of blocking device 214 can have a diameter D2. In some embodiments, diameter D1 can be greater than diameter D2, as shown in FIGS. 2A and 2B, such that blocking device 214 can partially block the end of tube 212. In some embodiments, diameter D1 can be substantially the same as diameter D2 or less than diameter D2, such that blocking device 214 can partially or fully block the end of tube 212, depending on the relative position between blocking device 214 and tube 212.

In some embodiments, when blocking device 214 partially blocks the end of tube 212, blocking device 214 and tube 212 can together form a ring-shape orifice 218, through which material 217 is dispersed into the chamber. Due to its cone shape, when blocking device 214 moves along the Z axis, a size of orifice 218 can be adjusted, hence a flowrate of material 217 passing through orifice 218 can be adjusted. Referring to a first configuration, as shown in FIGS. 2A and 2C, blocking device 214 is at a first position, such that bottom periphery 215 of blocking device 214 is substantially aligned with the end of tube 212, orifice 218 has a first size, which is an aerial difference between a first circle having diameter D1 and a second circle having a diameter S1. Referring to a second configuration, as shown in FIGS. 2B and 2D, blocking device 214 is at a second position, such that bottom periphery 215 of blocking device 214 is outside the end of tube 212 by a distance L, and orifice 218 has a second size greater than the first size, since the second size is an aerial difference between the first circle having diameter D1 and a third circle having a diameter S2 smaller than S1. In some embodiments, the size of orifice 218 can be calculated based on a width of the ring shape of orifice 218, such as D1-S1 and D1-S2. In some embodiments, the width of the ring shape of orifice 218 can be adjusted between about 0.2 mm and about 1.5 mm, and accordingly, the flowrate of material 217 can be adjusted between about 10,000 sccm and about 15,000 sccm. In some embodiments, if the width of the ring shape of orifice 218 is less than about 0.2 mm, the size of the orifice may be too small, such that orifice 218 is more susceptible to condensation or accumulation of material 217. In some embodiments, if the width of the ring shape of orifice 218 is greater than about 1.5 mm, it would take a longer time to adjust the position of the blocking device 214 along the Z axis, adversely impacting efficiency of the manufacturing operation. In some embodiments, if the flowrate of material 217 is less than about 10,000 sccm, the flowrate of material 217 may not be sufficient to remove material 217 condensed or accumulated at orifice 218. In some embodiments, if the flowrate of material 217 is greater than about 15,000 sccm, the flowrate of material 217 may be too high, unnecessarily wasting material 217.

In some embodiments, actuator 222 can include a spring 224 configured to retract blocking device 214 along the Z axis. In some embodiments, spring 224 can be configured to be in a relaxed state or a retracting state. In a relaxed state, spring 224 is not stretched, when bottom periphery 215 of blocking device 214 is substantially aligned with the end of tube 212 and the size of orifice 218 is minimized, as shown in FIG. 2A. In a retracting state, spring 224 is stretched, when bottom periphery 215 of blocking device 214 is outside the end of tube 212, as shown in FIG. 2B. In some embodiments, when material 217 is not flowing through tube 212, spring 224 can be configured to be in the relaxed state without retracting blocking device 214, such that bottom periphery 215 of blocking device 214 stays substantially aligned with the end of tube 212, as shown in FIGS. 2A and 2C. In some embodiments, when a manufacturing operation starts with material 217 flowing into tube 212 via channels 213, blocking device 214 can be configured to respond to an initial burst of material 217 (e.g., material 217 initially flowing through orifice 218) and be pushed by the initial burst outward of the end of tube 212 by a distance, thus increasing the size of orifice 218, as shown in FIGS. 2B and 2D. In some embodiments, after blocking device 214 is pushed by the initial burst, spring 224 is configured to gradually retract blocking device 214 back, until spring 224 returns to the relaxed state.

For example, the manufacturing operation can be a cleaning operation that lasts for a predetermined period of time, during which a cleaning solution flows through orifice 218 and dispersed onto a surface of a wafer (e.g., wafer 108 in FIG. 1A) to be cleaned. Blocking device 214 can be configured to be pushed outward by the cleaning solution initially flowing through orifice 218 to increase the size of orifice 218 and then gradually retract over the period of time to gradually decrease the size of orifice 218 when the cleaning solution continues flowing through orifice 218, until spring 224 returns to the relaxed state. In some embodiments, the predetermined period of time can be about 5 hours or less (e.g., about 1 hour, about 2 hours, about 3 hours, and about 4 hours), and spring 224 can be configured to retract blocking device 214 over a duration that substantially matches the predetermined period of time. For example, spring 224 can have an elastic constant providing a retraction force greater than a propel force of material 217 flowing through orifice 218, such that blocking device 214 can gradually retract over the predetermined period of time.

The adjustable size of orifice 218 of nozzle device 210 can provide improved uniformity of material 217 dispersed onto the wafer. When a manufacturing operation is performed, material 217 flowing through nozzle device 210 can deposit particles on inner surfaces of nozzle device 210, for example, on the inner surface of tube 212 or on the surface of blocking device 214. The particles deposited at or close to orifice 218 can impact the uniformity of material 217 dispersed onto the wafer. For example, the particles can partially block orifice 218, such that the flow of material 217 out of orifice 218 towards different directions becomes anisotropic, reducing the uniformity of material 217 dispersed onto the wafer. As described above, in response to the initial burst of material 217 flowing through the orifice, blocking device 214 is configured to increase the size of the orifice to adequately remove the particles blocking orifice 218, hence the uniformity of material 217 dispersed onto the wafer can be improved. Also, when blocking device 214 is retracted by spring 224, the relative motion between blocking device 214 and tube 212 can also prevent the particles deposited on the inner surface from accumulating between tube 212 and blocking device 214, facilitating smooth and even flow of material 217 through nozzle device 210.

In some embodiments, nozzle device 210 having spring 224 in actuator 222, as shown in FIGS. 2A and 2B, can function automatically in the sense that blocking device 214 can increase the size of the orifice in response to the initial burst of material 217 flowing through the orifice and then gradually reduce the size via retraction of spring 224, without being subject to further external control.

In some embodiments, actuator 222 can function according to external controls (e.g., by nozzle control device 130 in FIG. 1A, or by manual means) and adjust the position of blocking device 214 in a controllable manner different from implementing spring 224 to retract blocking device 214 automatically. For example, actuator 222 can include an electrical motor generating a rotational motion and can be coupled to a thread on rod 216, such that the rotational motion is transformed into a linear motion of blocking device 214 along the Z axis. In some embodiments, actuator 222 can include a manual knob, such that the position of blocking device 214 can be manually tuned by a user. In some embodiments, actuator 222 can be configured to include both the automatic function and external control as discussed above.

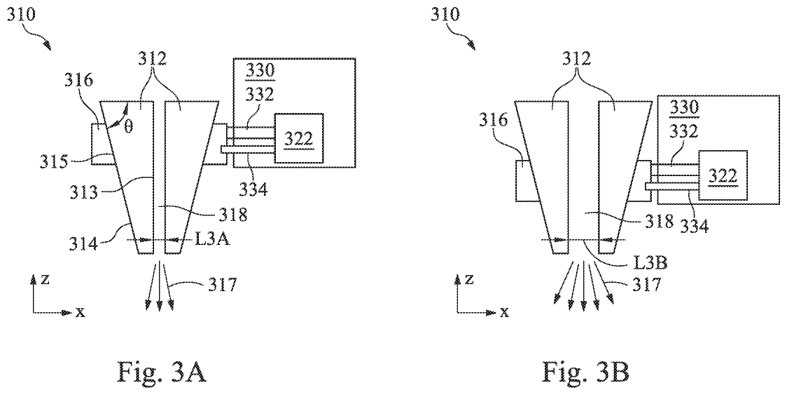

FIGS. 3A and 3B illustrate cross-sectional views of a nozzle device 310 having an adjustable configuration, in accordance with some embodiments. Nozzle device 310 can be one of the nozzle devices 110 in FIG. 1A. Nozzle device 310 can include arms 312 forming a passage 318, through which a material 317 can be delivered into a chamber (e.g., chamber 102 in FIG. 1A). In some embodiments, passage 318 can be surrounded by inner surfaces 313 of arms 312. In some embodiments, passage 318 can have a circular cross-sectional shape. In some embodiments, the cross section of passage 318 can be other shapes, such as a rectangular shape, a polygon shape, an oval shape, and an irregular shape. In some embodiments, nozzle device 310 can further include a sleeve 316. In some embodiments, an outer surface 314 of each of arms 312 and an inner surface 315 of sleeve 316 can be coupled to one another by matching screw threads on outer surface 314 and inner surface 315, such that a vertical position of arms 312 can be uniformly adjusted by rotating sleeve 316. In some embodiments, outer surface 314 of arms 312 and inner surface 315 of sleeve 316 can be slanted and have an angle θ with respect to a horizontal plane (e.g., in an X-direction), such that when the vertical position of arms 312 is adjusted by rotating sleeve 316, a distance between inner surfaces 313 of arms 312 can be adjusted accordingly, hence a size of passage 318 can be adjusted. For example, as shown in FIG. 3A, the size of passage 318 can have a first width L3A, and as shown in FIG. 3B, the size of passage 318 can have a second width L3B greater than the first width L3A. In some embodiments, a flowrate of material 317 through passage 318 can be adjusted according to the size of passage 318. In some embodiments, material 317 flowing through passage 318 with a greater width can have a greater flowrate.

In some embodiments, nozzle device 310 can further include a nozzle control device 330 configured to rotate sleeve 316. Nozzle control device 330 can be one of nozzle control devices 130 in FIG. 1A. As shown in FIGS. 3A and 3B, nozzle control device 330 can include an actuator 322 and a motion transmission mechanics 332. Actuator 322 is configured to provide linear and/or rotational motions, and motion transmission mechanics 332 is configured to apply and/or transform the linear and/or rotational motions to rotate sleeve 316. In some embodiments, actuator 322 can be an electrical motor, a hydraulic actuator, a pneumatic actuator, a magnetic actuator, a piezoelectric actuator, a shape-memory allay (SMA) actuator, a thermal actuator, and/or a combination thereof. In some embodiments, actuator 322 can include a micro stepper motor to fine tune the positions of arms 312, such that increment of the size of passage 318 can be as low as about 1% of a maximum size of passage 318. In some embodiments, actuator 322 can include a manual knob for manual control, and the manual knob can include increment markings quantitatively indicating the configurations of nozzle 320. In some embodiments, motion transmission mechanics 332 can include mechanical components, such as shafts, hinges, sleeves, gears, worm gears, gear racks, springs, stoppers, and/or a combination thereof. In some embodiments, nozzle control device 330 can further include a stopper 334 configured to fix sleeve 316 when actuator 322 is not driving sleeve 316 to rotate. In some embodiments, stopper 334 can prevent the size of passage 318 from changing due to unwanted perturbation, such as a vibration caused by the flowing of material 317, and hence stabilize the flowrate of material 317.

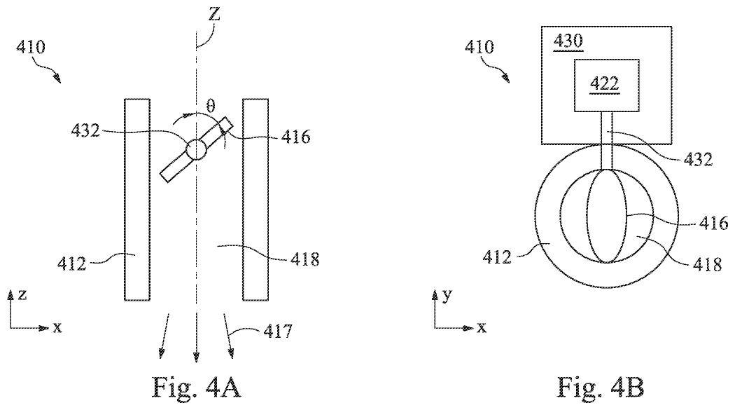

FIG. 4A illustrates a cross-sectional side view of a nozzle device 410 having an adjustable configuration, and FIG. 4B illustrates a cross-sectional top view of nozzle device 410, in accordance with some embodiments. Nozzle device 410 can be one of the nozzle devices 110 in FIG. 1A. Nozzle device 410 can include a tube 412 forming a passage 418 through which a material 417 can be supplied into a chamber (e.g., chamber 102 in FIG. 1A). In some embodiments, passage 418 can have a circular cross-sectional shape. In some embodiments, the cross section of passage 418 can be other shapes such as a rectangular shape, a polygon shape, an oval shape, and an irregular shape. Nozzle device 410 can further include a nozzle control device 430, which can include an actuator 422 and a motion transmission mechanics 432. The description of actuator 322 and motion transmission mechanics 332 with reference to FIGS. 3A and 3B applies to actuator 422 and motion transmission mechanics 432, unless mentioned otherwise. Nozzle device 410 can further include a valve 416 in passage 418 and configured to be rotated by actuator 422 via motion transmission mechanics 432. As shown in FIG. 4A, an angle θ of valve 416 with respect to a Z axis of tube 412 can be between about 0° and about 90°. Changing angle θ can adjust an effective cross section of material 417 flowing through tube 412, hence adjusting a flowrate of material 417.

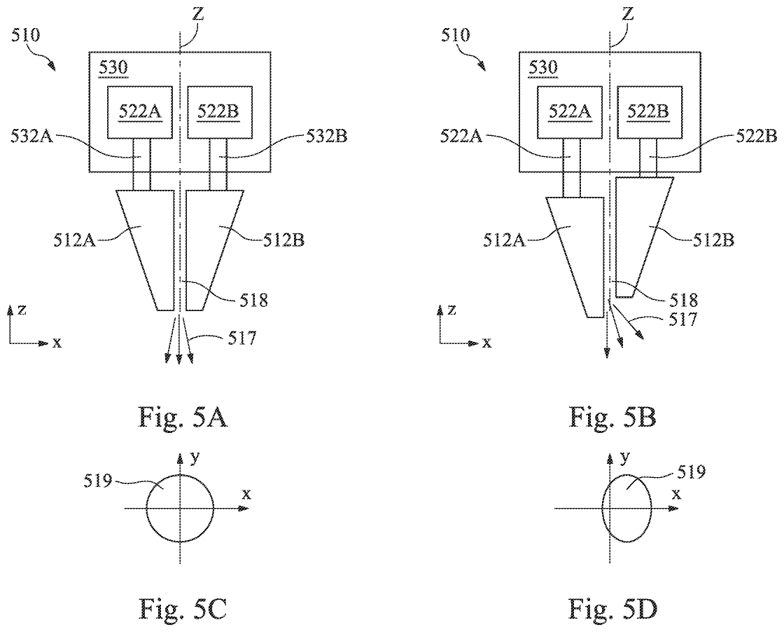

FIGS. 5A and 5B illustrate cross-sectional side views (e.g., along an X-Z plane) of a nozzle device 510 having an adjustable configuration, in accordance with some embodiments. Nozzle device 510 can be one of the nozzle devices 110 in FIG. 1A. Nozzle device 510 can include arms 512 (e.g., arms 512A and 512B) forming a passage 518, through which a material 517 can be supplied into a chamber (e.g., chamber 102 in FIG. 1A). Nozzle device 510 can further include a nozzle control device 530, which can include actuators 522 (e.g., actuators 522A and 522B) and motion transmission mechanics 532 (e.g., motion transmission mechanics 532A and 532B). Each of actuators 522 can be configured to control a vertical position and/or a horizontal position of one of arms 512 via one of motion transmission mechanics 532. For example, as shown in FIGS. 5A and 5B, actuator 522A can be configured to control a vertical position and/or a horizontal position of arm 512A via motion transmission mechanics 532A, and actuator 522B can be configured to control a vertical position and/or a horizontal position of arm 512B via motion transmission mechanics 532B. The description of actuator 322 and motion transmission mechanics 332 in FIGS. 3A and 3B applies to actuator 522 and motion transmission mechanics 532, unless mentioned otherwise. In some embodiments, horizontal positions of arms 512 can be adjusted to adjust a horizontal distance between arms 512, hence the flowrate of material 517 can be adjusted, similar to the embodiment discussed above as shown in FIGS. 3A and 3B.

In some embodiments, vertical positions of arms 512 can be adjusted to adjust a direction of dispersing material 517. FIGS. 5C and 5D illustrate a planar distribution 519 of material 517 dispersed onto a horizontal plane (e.g., a plane of an X-Y coordinate), corresponding to configurations of the vertical positions of arms 512 in FIGS. 5A and 5B, respectively, in accordance with some embodiments. An origin of the X-Y coordinate corresponds to a Z axis of passage 518. In some embodiments, vertical positions of arms 512 can be adjusted differently, so that planar distribution 519 can be adjusted. For example, as shown in FIGS. 5A and 5C, the vertical position of arm 512A is substantially the same as the vertical position of arm 512B, material 517 is dispersed in a substantially even manner with respect to the Z axis, and planar distribution 519 is symmetrical with respect to the origin of the X-Y coordinates. In another example, as shown in FIGS. 5B and 5D, the vertical position of arm 512A is lower than the vertical position of arm 512B and material 517 is dispersed in an uneven manner with respect to the Z axis, with more material 517 dispersed to the right hand side than to the left hand side. Further, planar distribution 519 is asymmetrical with respect to the origin of the X-Y coordinates, shifting positively towards the X direction.

During a manufacturing process, material 517 flowing through nozzle device 510 can deposit particles on inner surfaces of passage 518, affecting the uniformity of the dispersion of material 517. For example, the particles partially blocking passage 518 can cause a deviation of planar distribution 519 away from a substantially even manner with respect to the Z axis. In some embodiments, adjusting planar distribution 519 by adjusting vertical positions of one or more arms 512 can mitigate particles blocking passage 518 and improve the uniformity of the dispersion of material 517.

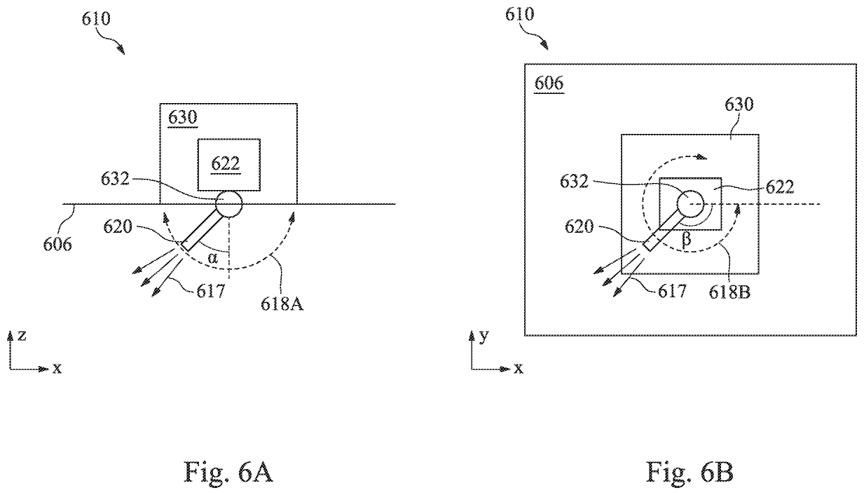

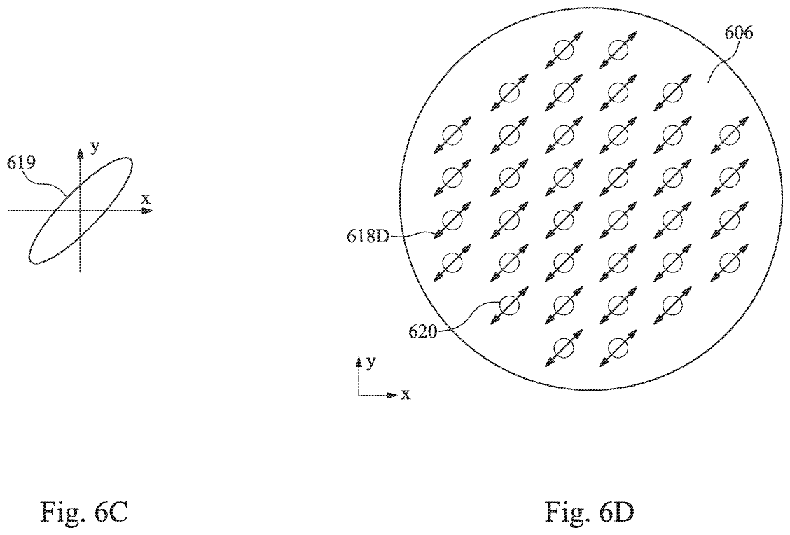

FIG. 6A illustrates a cross-sectional side view (e.g., along an X-Z plane) of a nozzle device 610 having an adjustable configuration, and FIG. 6B illustrates a cross-sectional top view (e.g., along an X-Y plane) of nozzle device 610, in accordance with some embodiments. Nozzle device 610 can be one of the nozzle devices 110 in FIG. 1A. Nozzle device 610 can include a nozzle 620 disposed on a showerhead 606 to supply a material 617 into a chamber (e.g., chamber 102 in FIG. 1A). Nozzle device 610 can further include a nozzle control device 630 disposed on showerhead 606. Nozzle control device 630 can include an actuator 622 and a motion transmission mechanics 632. The description of actuator 322 and motion transmission mechanics 332 in FIGS. 3A and 3B applies to actuator 622 and motion transmission mechanics 632, unless mentioned otherwise.

In some embodiments, nozzle 620 and motion transmission mechanics 632 can be coupled in a ball-joint configuration, such that a direction of nozzle 620 can be adjusted. In some embodiments, as shown in FIG. 6A, the direction of nozzle 620 can be adjusted within the X-Z plane, and an angle α between nozzle 620 and a vertical direction can be in a range 618A. For example, angle α can be between about 0° and about 30°, between about 0° and about 45°, between about 0° and about 60°, or between about 0° and about 90°. In some embodiments, as shown in FIG. 6B, the direction of nozzle 620 can be adjusted within in a range 618B, with an angle β between a projection of the direction of nozzle 620 on the X-Y plane and the X axis. For example, angle β can be adjusted in range 618B that covers an entire 360° range or can be one or more fixed values. In some embodiments, the direction of nozzle 620 can be adjusted in both degrees of freedom as described above. In some embodiments, the direction of nozzle 620 can be adjusted in only one of the two degrees of freedom as described above. For example, nozzle 620 can be configured to have angle β fixed and angle α adjustable in a range, and a planar distribution 619 of material 617 dispersed onto a horizontal plane (e.g., the X-Y plane) is illustrated in FIG. 6C, which shows an oval shape of planar distribution 619. In some embodiments, as shown in FIG. 6D, nozzles 620 are configured to be adjustable in the same degree of freedom (as shown by the double arrows 618D) and can be mounted on showerhead 606.

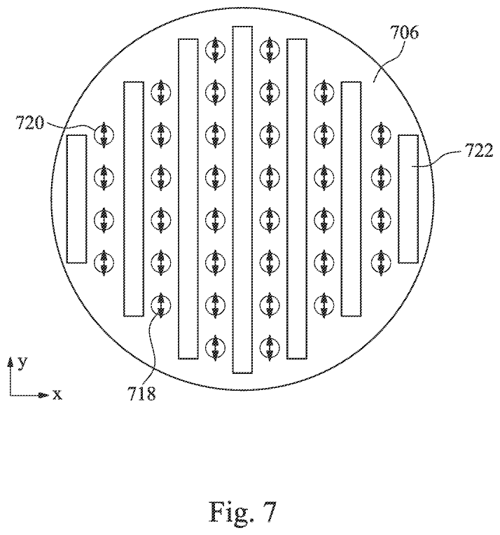

FIG. 7 illustrates a bottom view of a showerhead 706 with nozzles 720 mounted on a showerhead 706, in accordance with some embodiments. A direction of nozzles 720 is adjustable. For example, each nozzle 720 can include a ball-joint structure, similar to nozzle 620 as shown in FIGS. 6A and 6B. In some embodiments, each nozzle 720 includes a magnetic material and is configured to change the direction in response to a magnetic field. In some embodiments, magnetic actuators 722 can be disposed on showerhead 706 and adjacent to nozzles 720. Each magnetic actuator 722 can include one or more electromagnets (e.g., solenoids) and can generate the magnetic field with parameters (e.g., a strength and/or an orientation of the magnetic field at positions of nozzles 720) controlled by electrical currents running through the electromagnets. Therefore, the directions of nozzles 720 can be adjusted by controlled electrical currents running through the electromagnets of magnetic actuators 722. For example, as shown in FIG. 7, nozzles 720 can be configured to have their directions adjustable along the Y-direction, as indicated by double arrows 718. In some embodiments, nozzles 720 can be configured to have their directions adjustable in two degrees of freedom. In some embodiments, parameters of the electrical currents running through the electromagnets of magnetic actuators 722 can be controlled by a control device, such as control device 150 in FIG. 1A.

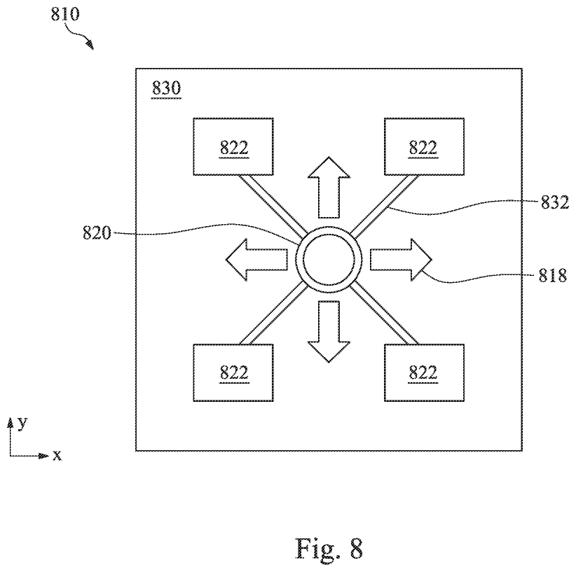

FIG. 8 illustrates a bottom view of a nozzle device 810 having an adjustable configuration, in accordance with some embodiments. Nozzle device 810 can be one of the nozzle devices 110 in FIG. 1A. Nozzle device 810 can include a nozzle 820, through which a material can be supplied into a chamber (e.g., chamber 102 in FIG. 1A). A direction of nozzle 820 is configured to be adjustable. For example, nozzle 820 can include a ball-joint structure, similar to nozzle 620 as shown in FIGS. 6A and 6B. Nozzle device 810 can further include a nozzle control device 830, which can include electrical current sources 822 and shape metal alloy lines 832. Each electrical current source 822 is configured to supply an electrical current to shape metal alloy line 832. Shape metal alloy line 832 is configured to deform in response to the electrical current. For example, shape metal alloy line 832 can be configured to extend, shrink, or bend, when supplied with the electrical current. In some embodiments, an amount of deformation of shape metal alloy lines 832 can be a function of the electrical current. Shape metal alloy lines 832 can be attached to nozzle 820, and the deformation of shape metal alloy lines 832 can adjust the direction of nozzle 820. Therefore, the direction of nozzle 820 can be controlled by adjusting electrical currents supplied to shape metal alloy lines 832. For example, as shown in FIG. 8, nozzle 820 can be configured to have its direction adjustable in two degrees of freedoms as indicated by arrows 818. In some embodiments, electrical current sources 822 can be controlled by a control device (e.g., control device 150 in FIG. 1A) to adjust the direction of nozzle 820 to improve a uniformity of the material supplied into the chamber through nozzle 820 and dispersed onto a wafer.

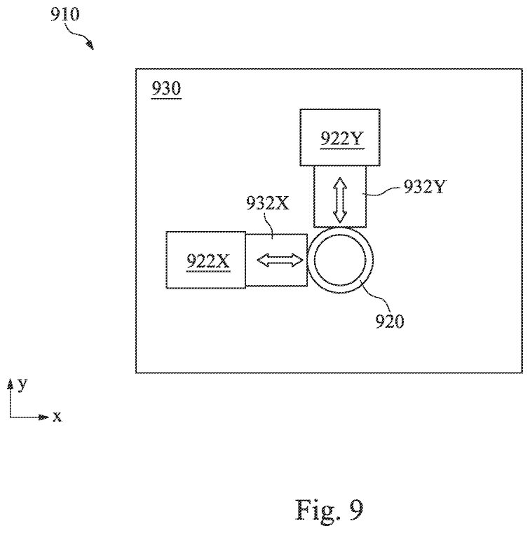

FIG. 9 illustrates a bottom view of a nozzle device 910 having an adjustable configuration, in accordance with some embodiments. Nozzle device 910 can be one of the nozzle devices 110 in FIG. 1A. Nozzle device 910 can include a nozzle 920, through which a material can be supplied into a chamber (e.g., chamber 102 in FIG. 1A). A direction of nozzle 920 can be adjustable. For example, nozzle 920 can include a ball-joint structure, similar to nozzle 620 as shown in FIGS. 6A and 6B. Nozzle device 910 can further include a nozzle control device 930, which can include temperature controllers 922X and 922Y and bimetallic strips 932X and 932Y. Temperature controllers 922X and 922Y are configured to control temperatures of bimetallic strips 932X and 932Y, respectively. Bimetallic strips 932X and 932Y are configured to deform in response to their temperatures. For example, bimetallic strip 932X can be configured to extend or shrink along the X-direction when its temperature increases or decreases. Similarly, bimetallic strip 932Y can be configured to extend or shrink along the y-direction when its temperature increases or decreases. Bimetallic strips 932X and 932Y can be attached to nozzle 920, and the deformation of bimetallic strips 932X and 932Y can adjust the direction of nozzle 920. Therefore, the direction of nozzle 920 can be adjusted by controlling the temperatures of bimetallic strips 932X and 932Y. As shown in FIG. 9, nozzle 920 can be configured to have its direction adjustable in two degrees of freedom (e.g. X and Y directions). In some embodiments, temperature controllers 922X and 922Y can be controlled by a control device (e.g., control device 150 in FIG. 1A) to adjust the direction of nozzle 820 to improve a uniformity of the material supplied into the chamber through nozzle 920 and dispersed onto a wafer.

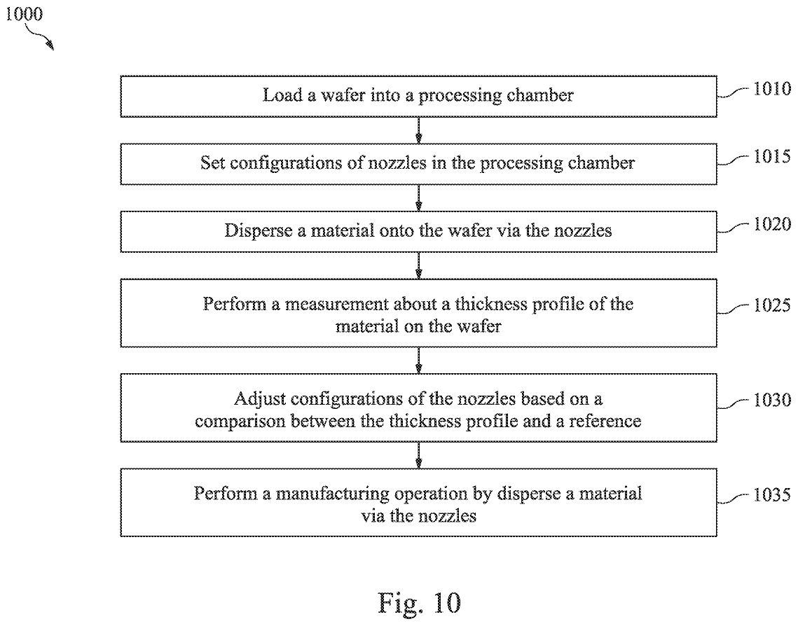

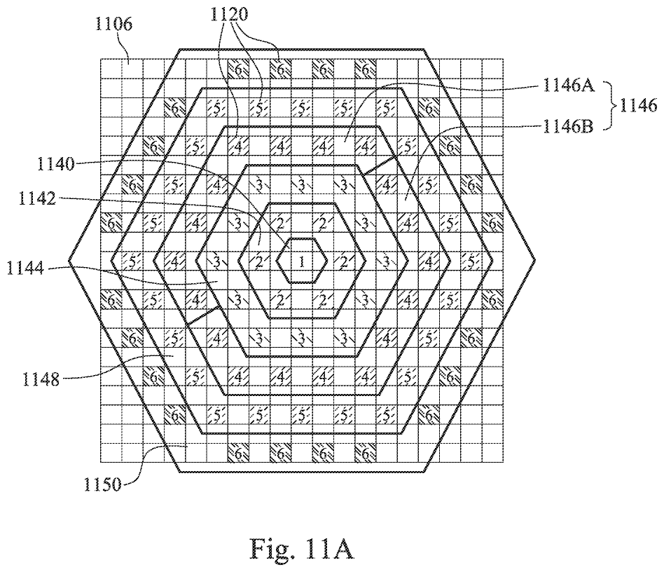

FIG. 10 illustrates a flow diagram of an example method 1000 for performing a semiconductor manufacturing process with a nozzle device, according to some embodiments. For illustrative purpose, the operations illustrated in FIG. 10 are described with reference to system 100 in FIG. 1A. Although operations of method 1000 can be performed in an order as shown in FIG. 10, it should be noted that, depending on specific applications, the operations of method 1000 can be performed in a different order, and some of the operations may not be performed. Accordingly, it is understood that additional operations can be performed before, during, and after method 1000, and these additional processes may only be briefly described herein.

Referring to FIG. 10, in operation 1010, a wafer is loaded into a processing chamber. For example, as described with reference to FIG. 1A, wafer 108 can be placed and/or secured on wafer holder 104 in chamber 102. Wafer 108 can be placed in a horizontal or tilted position, with an upper surface of wafer 108 exposed to nozzles 120 disposed on showerhead 106 above wafer holder 104.

Referring to FIG. 10, in operation 1015, configurations of nozzles in the processing chamber can be set. For example, as described with reference to FIG. 1A, control device 150 can send commands to nozzle control devices 130 to set configurations of nozzles 120. Configurations of each of nozzles 120, such as a direction of the nozzle, a size of the passage in the nozzle, and/or a flowrate of the material through the nozzle, can be set. In some embodiments, configurations of nozzles 120 can be set according to a predetermined profile. In some embodiments, the configurations of all of nozzles 120 can be set uniformly. In some embodiments, configurations of different nozzles 120 can be set differently, according to specific requirements of the semiconductor manufacturing process.

Referring to FIG. 10, in operation 1020, a material can be supplied into the processing chamber via the nozzles and dispersed onto the wafer. For example, as described with reference to FIG. 1A, material supply device 152 can receive commands from control device 150 to choose a material stored in material supply device 152 and supply the material through material supply channel 154 to nozzles 120. The material is further dispersed by nozzles 120 onto wafer 108. In some embodiments, the configurations of nozzles 120 can affect a uniformity of the material dispersed onto wafer 108. In some embodiments, other conditions of nozzles 120, such as depositions/accumulations of the material in nozzles 120, can affect the uniformity of the layer of the material dispersed onto wafer 108.

Referring to FIG. 10, in operation 1025, a thickness profile of the material dispersed onto the wafer can be measure. For example, as described with reference to FIG. 1A, analyzer device 158 can receive commands from control device 150 to perform a measurement about the thickness profile of the material dispersed onto wafer 108. The thickness profile can reflect the uniformity of the material dispersed onto wafer 108. In some embodiments, analyzer device 158 can scan a portion or an entirety of a top surface of wafer 108 to measure the thickness profile. In some embodiments, analyzer device 158 can sample discrete locations on the top surface of wafer 108 to measure the thickness profile. In some embodiments, data about the thickness profile can be collected by analyzer device 158 and sent to control device 150 for further processing.

Referring to FIG. 10, in operation 1030, the configurations of the nozzles can be adjusted based on a comparison between the a thickness profile and a reference. For example, as described with reference to FIG. 1A, after receiving the data about the thickness profile, control device 150 can compare the thickness profile to a reference profile. For example, control device 150 can calculate a difference between the thickness profile and the reference profile. Based on the comparison, control device 150 can perform a calculation or a simulation to determine a scheme to adjust the configurations of some or all of nozzles 120, in order to improve the uniformity of the material dispersed onto wafer 108. According to the scheme, control device 150 can send commands to nozzle control devices 130 to adjust the configurations of the nozzles 120. In some embodiments, the reference profile can be a reference thickness profile about a uniformity of a layer of the material on the wafer predetermined based on a quality control requirement.

Referring to FIG. 10, in operation 1035, after adjusting the configurations of the nozzles, a semiconductor manufacturing operation can be performed by dispersing the material via the nozzles. In some embodiments, similar to operation 1020, in operation 1035, the material can be supplied into the processing chamber via the nozzles and dispersed onto the wafer. In some embodiments, operation 1035 can include replacing the wafer (which has been used to measure the thickness profile in operation 1025) with a new wafer and performing the manufacturing operation on the new wafer by dispersing the material onto the new wafer. In some embodiments, the semiconductor manufacturing operation can be a deposition of a layer of the material onto the wafer or the new wafer. In some embodiments, the semiconductor manufacturing operation can be a clean operation to remove contaminations on the wafer, with the material being a cleaning solution.

In some embodiments, after performing operation 1035, method 1000 can proceed by unloading the wafer from the processing chamber. In some embodiments, after performing operation 1035, method 1000 can proceed by repeating operations 1025, 1030, and 1035, such that an updated thickness profile can be measured, and the configurations of the nozzles can be readjusted to further improve the uniformity of the material dispersed onto the wafer. In some embodiments, operations 1025, 1030, and 1035 can be performed repeatedly until the uniformity reaches a predetermined level determined by a quality control requirement. In some embodiments, operations 1025, 1030, and 1035 can be performed simultaneously. For example, while the material is dispersed onto the wafer, the thickness profile of the material on the wafer is measured and compared to a reference profile and the configurations of the nozzles are adjusted accordingly in real time.

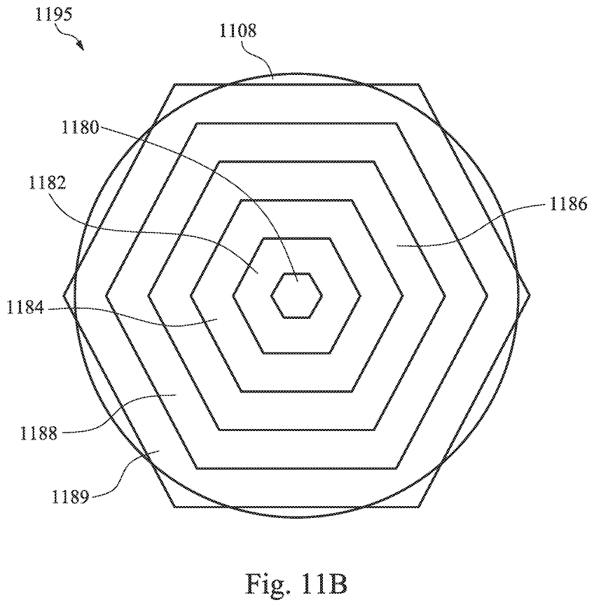

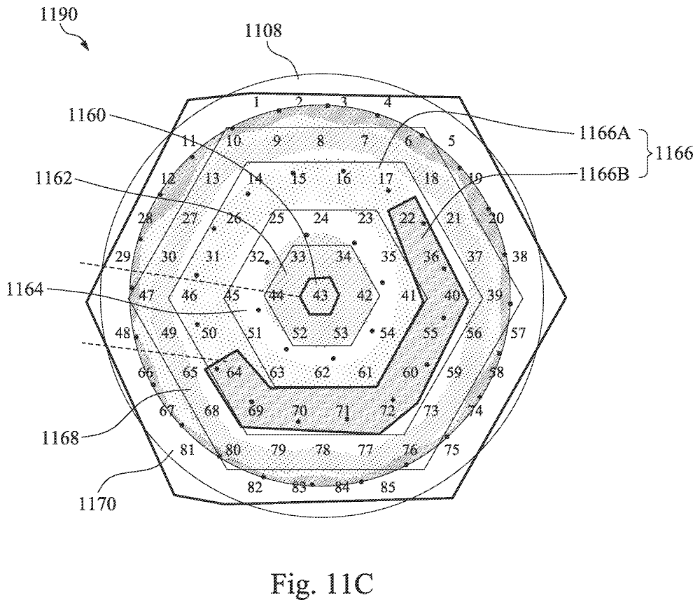

FIG. 11A illustrates configurations of nozzles 1120 on a showerhead 1106, according to some embodiments. FIG. 11B illustrates a reference profile 1195 of a material dispersed onto wafer 1108 via nozzles 1120 as shown in FIG. 11A, according to some embodiments. FIG. 11C illustrates a thickness profile 1190 of the material dispersed onto a wafer 1108 via nozzles 1120 as shown in FIG. 11A, according to some embodiments.

Referring to FIG. 11A, showerhead 1106 is divided into multiple showerhead sections 1140, 1142, 1144, 1146, 1148, and 1150, according to a six-fold rotational symmetry. Nozzles 1120 within each showerhead section have substantially the same configuration. Nozzles 1120 between different showerhead sections have different configurations. For example, flowrates of nozzles 1120 in showerhead sections 1140, 1142, 1144, 1146, 1148, and 1150 can be ‘x’ sccm, ‘x−3’ sccm, ‘x−6’ sccm, ‘x−9’ sccm, ‘x−12’ sccm, and ‘x−15’ sccm, respectively, with ‘x’ being a value greater than 15. The configurations of nozzles 1120 set as shown in FIG. 11A can be used to calibrate nozzles 1120. Those skilled in the art should understand that, depending on the specific requirement of the calibration, showerhead 1106 can be divided into multiple showerhead sections in a different manner, and the configurations of nozzles 1120 in different showerhead sections can be set in a different manner.

Referring to FIG. 11B, reference profile 1195 can be a predetermined profile that represents a uniformity of the material dispersed onto wafer 1108 when nozzles 1120 function as intended, according to the configurations of nozzles 1120 as shown in FIG. 11A. Corresponding to the different showerhead sections 1140, 1142, 1144, 1146, 1148, and 1150 as shown in FIG. 11A, wafer 1108 can be divided into different wafer sections 1180, 1182, 1184, 1186 1188, and 1189. Reference profile 1195 in different wafer sections can reflect the configurations difference of nozzles 1120 in different showerhead sections. For example, reference profile 1195 within each of the wafer sections can be substantially uniform, and reference profile 1195 in different wafer sections can be different.

Referring to FIG. 11C, thickness profile 1190 can be measured by an analyzer (e.g., analyzer device 158 in FIG. 1A), as discussed in operation 1025 as shown in FIG. 10. Corresponding to the different showerhead sections 1140, 1142, 1144, 1146, 1148, and 1150 as shown in FIG. 11A, wafer 1108 can be divided into different wafer sections 1160, 1162, 1164, 1166 (including wafer subsections 1166A and 1166B), 1168, and 1170. Thickness profile 1190 in different wafer sections can reflect the configurations difference of nozzles 1120 in different showerhead sections. For example, thickness profile 1190 within each of the wafer sections can be substantially uniform, and thickness profile 1190 in different wafer sections can be different. It is possible that certain nozzles do not function as intended, due to factors such blockage of material accumulated in the nozzles. As shown in FIG. 11C, thickness profile 1190 indicates that thicknesses in wafer subsections 1166A and 1166B are measured to be different. For example, the thickness in wafer subsection 1166A is less than the thickness in wafer subsection 1166B. In some embodiments, as discussed in operation 1030 as shown in FIG. 10, thickness profile 1190 can be compared with reference profile 1195 as shown in FIG. 11B to determine a scheme to adjust the configurations of nozzle 1120, so that the uniformity of the layer of the material dispersed onto wafer 1108 or a new wafer can be improved. As shown in FIGS. 11A and 11C, showerhead section 1146 can be divided into showerhead subsections 1146A and 1146B corresponding to wafer subsections 1166A and 1166B, respectively. Nozzles in showerhead subsections 1146A and 1146B can be adjusted differently, according to the comparison of thickness profile 1190 and reference profile 1195, as discussed in operation 1030 as shown in FIG. 10. For example, if the thickness in wafer subsection 1166A of thickness profile 1190 is less than the thickness in wafer subsection 1186 of reference profile 1195, and/or if the thickness in wafer subsection 1166B of thickness profile 1190 is greater than the thickness in wafer subsection 1186 of reference profile 1195, a flowrate of nozzles in showerhead subsections 1146A can be increased to be higher than a flowrate of nozzles in showerhead subsections 1146B, so that the thickness difference in wafer subsections 1166A and 1166B can be compensated.

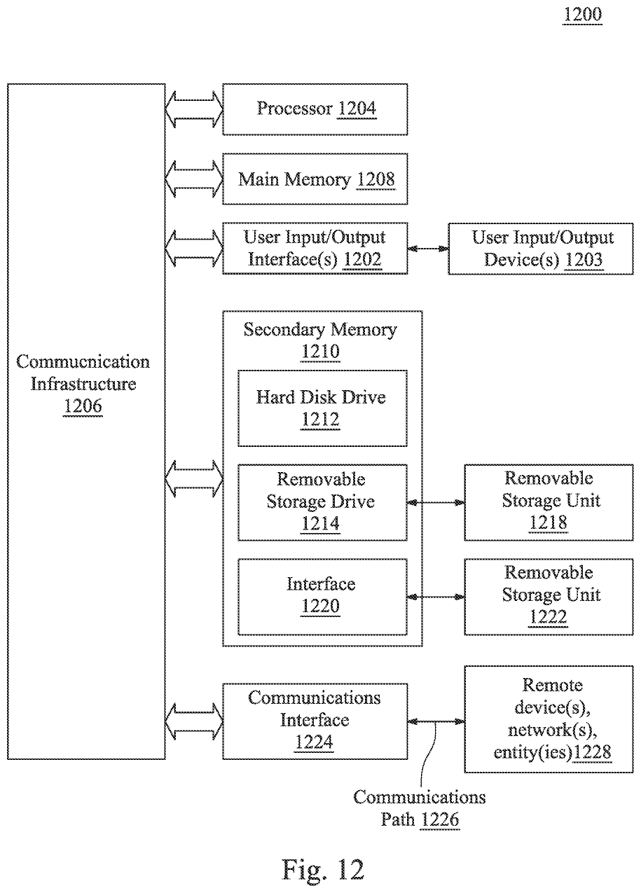

FIG. 12 is a block diagram of example components of computer system 1200, in accordance with some embodiments. One or more computer systems 1200 can be used, for example, to implement any of the embodiments discussed herein, as well as combinations and sub-combinations thereof. In some embodiments, one or more computer systems 1200 can be used to implement the method 1000 as shown in FIG. 10 to operate system 100 as shown in FIG. 1A. For example, computer systems 1200 can be used to operate control device 150, material supply device 152, analyzer device 158, and/or nozzle devices 110 as shown in FIG. 1A. Computer system 1200 can include one or more processors (also called central processing units, or CPUs), such as a processor 1204. Processor 1204 can be connected to a communication infrastructure 1206.

Computer system 1200 can also include user input/output interface(s) 1202, such as monitors, keyboards, and pointing devices, which can communicate with communication infrastructure 1206 through user input/output interface(s) 1203.

One or more of processors 1204 can be a graphics processing unit (GPU). In an embodiment, a GPU can be a processor that is a specialized electronic circuit designed to process mathematically intensive applications. The GPU can have a parallel structure that is efficient for parallel processing of large blocks of data, such as mathematically intensive data common to computer graphics applications, images, and videos.

Computer system 1200 can also include a main or primary memory 1208, such as a random access memory (RAM). Main memory 1208 can include one or more levels of cache. Main memory 1208 can have stored therein control logic (e.g., computer software) and/or data. In some embodiments, main memory 1208 can include optical logic configured to perform analysis of optical measurements obtained from an analyzer, such as analyzer device 158 as shown in FIG. 1A.

Computer system 1200 can also include one or more secondary storage devices or memory 1210. Secondary memory 1210 can include, for example, a hard disk drive 1212 and/or a removable storage drive 1214. In some embodiments, secondary memory 1208 can be configured to store data, such as data collected by analyzer device 158 about a thickness profile of a material dispersed onto wafer 108, as shown in FIG. 1A, and/or data about a reference used to compare with the thickness profile to determine a scheme to adjust the configurations of nozzles 120.

Removable storage drive 1214 can interact with a removable storage unit 1218. Removable storage unit 1218 can include a computer usable or readable storage device having stored thereon computer software (control logic) and/or data. Removable storage unit 1218 can be a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. Removable storage drive 1214 can read from and/or write to removable storage unit 1218.

Secondary memory 1210 can include other means, devices, components, instrumentalities or other approaches for allowing computer programs and/or other instructions and/or data to be accessed by computer system 1200. Such means, devices, components, instrumentalities or other approaches can include, for example, a removable storage unit 1222 and an interface 1220. Examples of the removable storage unit 1222 and the interface 1220 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 1200 can further include a communication or network interface 1224. Communication interface 1224 can enable computer system 1200 to communicate and interact with any combination of external devices, external networks, and external entities (individually and collectively referenced by reference number 1228). For example, communication interface 1224 can allow computer system 1200 to communicate with external or remote devices 1228 over communications path 1226, which can be wired and/or wireless (or a combination thereof), and which can include any combination of LANs, WANs, and the Internet. Control logic and/or data can be transmitted to and from computer system 1200 via communication path 1226. In some embodiments, computer system 1200 can be coupled to a catheter via a connector and optical and electrical connections at communication interface 1224, including optical fibers and electrical wiring, pins, and/or components.

Computer system 1200 can also be any of a personal digital assistant (PDA), desktop workstation, laptop or notebook computer, netbook, tablet, smartphone, smartwatch or other wearables, appliance, part of the Internet-of-Things, and/or embedded system, to name a few non-limiting examples, or any combination thereof.

Computer system 1200 can be a client or server, accessing or hosting any applications and/or data through any delivery paradigm, including but not limited to remote or distributed cloud computing solutions; local or on-premises software (“on-premise” cloud-based solutions); “as a service” models (e.g., content as a service (CaaS), digital content as a service (DCaaS), software as a service (SaaS), managed software as a service (MSaaS), platform as a service (PaaS), desktop as a service (DaaS), framework as a service (FaaS), backend as a service (BaaS), mobile backend as a service (MBaaS), and infrastructure as a service (IaaS)); and/or a hybrid model including any combination of the foregoing examples or other services or delivery paradigms.

Any applicable data structures, file formats, and schemas in computer system 1200 can be derived from standards including but not limited to JavaScript Object Notation (JSON), Extensible Markup Language (XML), Yet Another Markup Language (YAML), Extensible Hypertext Markup Language (XHTML), Wireless Markup Language (WML), MessagePack, XML User Interface Language (XUL), or any other functionally similar representations alone or in combination. Alternatively, proprietary data structures, formats or schemas can be used, either exclusively or in combination with known or open standards.

In some embodiments, a tangible, non-transitory apparatus or article of manufacture comprising a tangible, non-transitory computer useable or readable medium having control logic (software) stored thereon can also be referred to herein as a computer program product or program storage device. This includes, but is not limited to, computer system 1200, main memory 1208, secondary memory 1210, and removable storage units 1218 and 1222, as well as tangible articles of manufacture embodying any combination of the foregoing. Such control logic, when executed by one or more data processing devices (such as computer system 1200), can cause such data processing devices to operate as described herein.

The present disclosure provides example apparatus and methods for semiconductor manufacturing processes using an adjustable nozzle device. The apparatus includes a wafer holder configured to hold a wafer, a nozzle disposed above the wafer and configured to provide a material to the wafer, and a nozzle control device configured to adjust a configuration of the nozzle to improve a uniformity of a layer of the material disposed onto the wafer. The method includes loading the wafer into a chamber, feeding the material into the chamber through the nozzle, measuring a thickness profile of a layer of the material disposed onto the wafer, and adjusting a configuration of the nozzle based on a comparison between the thickness profile and a reference. In some embodiments, adjusting the configuration of the nozzles can improve the uniformity of the layer of the material disposed onto the wafer. In some embodiments, adjusting the configuration of the nozzles can adequately resolve issues caused by the deposition, accumulation, or condensation of the material in the nozzles and can also reduce time and efforts for tool maintenance in semiconductor manufacturing processes.

In some embodiments, an apparatus includes a wafer holder configured to hold a wafer and a nozzle disposed above the wafer holder. The nozzle includes an orifice configured to provide a material to the wafer, a blocking device disposed at the orifice and configured to adjust a size of the orifice, and an actuator configured to adjust the position of the blocking device through the orifice.

In some embodiments, an apparatus includes a wafer holder configured to hold a wafer, a showerhead above the wafer holder, a nozzle on the showerhead, and an actuator. The nozzle is configured to provide a material to the wafer through a passage in the nozzle and control a flowrate of the material. The actuator is configured to adjust the passage to improve a uniformity of the material disposed onto the wafer.

In some embodiments, a method includes loading a wafer into a chamber, feeding, a material into the chamber through a nozzle, measuring a thickness profile of the material disposed onto the wafer, and adjusting an opening of the nozzle based on the thickness profile.

The foregoing disclosure outlines features of several embodiments so that those skilled in the art can better understand the aspects of the present disclosure. Those skilled in the art should appreciate that they can readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they can make various changes, substitutions, and alterations herein without departing from the spirit and scope of the present disclosure.

What is claimed is:

1. An apparatus, comprising:
a wafer holder configured to hold a wafer;
a nozzle disposed above the wafer holder, wherein the nozzle comprises:
an orifice configured to provide a material to the wafer; and
a blocking device disposed at the orifice and configured to adjust a size of the orifice; and
an actuator configured to adjust a position of the blocking device through the orifice.

2. The apparatus of claim 1, wherein the blocking device is further configured to:
increase the size of the orifice in response to the material initially flowing through the orifice; and
decrease the size of the orifice during a predetermined period of time associated with the material flowing through the orifice.

3. The apparatus of claim 1, wherein a width of the orifice is adjustable between about 0.2 mm and about 1.5 mm.

4. The apparatus of claim 1, wherein the blocking device has a cone shape.

5. The apparatus of claim 1, wherein the actuator is further configured to retract the blocking device to decrease the size of the orifice.

6. The apparatus of claim 5, wherein the actuator is further configured to retract the blocking device over a duration of about 4 hours.

7. The apparatus of claim 1, wherein the actuator comprises:
a rod connected to the blocking device; and
a spring connected to the rod and configured to retract the blocking device.

8. The apparatus of claim 1, wherein the nozzle is configured to flow the material at a flowrate between about 10,000 sccm and about 15,000 sccm.

9. An apparatus, comprising:
a wafer holder configured to hold a wafer;
a showerhead above the wafer holder;
a nozzle on the showerhead and configured to:
provide, to the wafer, a material through a passage in the nozzle; and
control a flowrate of the material; and
an actuator configured to adjust the passage to improve a uniformity of the material disposed onto the wafer.

10. The apparatus of claim 9, wherein the nozzle comprises a plurality of arms configured to form the passage.

11. The apparatus of claim 10, wherein the nozzle further comprises a rotational sleeve coupled to threads on the plurality of arms, wherein the rotational sleeve is configured to control a size of the passage to control the flowrate of the material.

12. The apparatus of claim 11, wherein the actuator is configured to rotate the rotational sleeve.

13. The apparatus of claim 10, wherein the actuator is further configured to control a vertical position of one or more of the plurality of arms to adjust a dispersing direction of the material.

14. The apparatus of claim 9, wherein the actuator is further configured to adjust the passage based on calibration data associated with the uniformity of the material disposed onto the wafer.

15. The apparatus of claim 9, wherein the actuator comprises an electrical actuator, a hydraulic actuator, a pneumatic actuator, a magnetic actuator, a piezoelectric actuator, a shape memory alloy actuator, a thermal actuator, or a combination thereof.

16. A method, comprising:
loading a wafer into a chamber;
feeding, through a nozzle, a material into the chamber;
measuring a thickness profile of the material disposed onto the wafer; and
adjusting an opening of the nozzle based on the thickness profile.

17. The method of claim 16, wherein adjusting the opening of the nozzle comprises adjusting a direction of the opening of the nozzle.

18. The method of claim 16, wherein adjusting the opening of the nozzle comprises adjusting a size of the opening of the nozzle.

19. The method of claim 16, wherein adjusting the opening of the nozzle comprises adjusting the opening of the nozzle based on a difference between the thickness profile and a predetermined reference profile.

20. The method of claim 16, further comprising:
feeding, through an other nozzle, the material into the chamber; and
adjusting an opening of the other nozzle based on a uniformity of the thickness profile, wherein a flowrate of the material through the nozzle is different from that through the other nozzle.
